(19) United States
(12) Patent Application Publication
(10) Pub. No.: US 2013/0180952 A1
(43) Pub. Date: Jul. 18, 2013

(54) PRESSURE MASKING SYSTEMS AND METHODS FOR USING THE SAME

(71) Applicant: General Electric Company, Schenectady, NY (US)

(72) Inventors: Matthew Paul Berkebile, Pooler, GA (US); Mark Lawrence Hunt, Simpsonville, SC (US); Blake Allen Fulton, Simpsonville, SC (US)

(73) Assignee: General Electric Company, Schenectady, NY (US)

(21) Appl. No.: 13/826,465

(22) Filed: Mar. 14, 2013

Related U.S. Application Data
(63) Continuation-in-part of application No. 13/339,449, filed on Dec. 29, 2011.
Application No. 13/339,449 is a continuation-in-part of application No. 13/339,468, filed on Dec. 29, 2011.

(51) Int. Cl. B05C 21/00; C25D 5/02

(52) U.S. Cl. CPC B05C 21/005; C25D 5/022
USPC 216/41; 427/282; 118/504; 156/345.3; 205/118; 204/275.1

(57) ABSTRACT

Methods of treating a target surface of an article having one or more passageways includes fluidly connecting a pressure masker including pressurized masking fluid to a first side of at least one passageway, passing the pressurized masking fluid through the at least one passageway from the first side to a second side having the target surface, and treating the target surface of the article using a surface treatment system that disposes a surface treating material on the target surface, wherein the pressurized masking fluid passing through the at least one passageway prevents the surface treating material from permanently altering a cross sectional area of the at least one passageway.

### CROSS REFERENCE TO RELATED APPLICATIONS

This application is a continuation-in-part to U.S. patent application Ser. No. 13/339,468, filed on Dec. 29, 2011 and U.S. patent application Ser. No. 13/339,449, filed on Dec. 29, 2011 both of which are fully incorporated herein by reference and made a part hereof.

### BACKGROUND OF THE INVENTION

The subject matter disclosed herein relates to masking systems and, more specifically, to pressure masking systems for treating articles with passageways.

In gas turbine engines, such as aircraft engines for example, air is drawn into the front of the engine, compressed by a shaft-mounted rotary-type compressor, and mixed with fuel. The mixture is burned, and the hot exhaust gases are passed through a turbine mounted on a shaft. The flow of gas turns the turbine, which turns the shaft and drives the compressor and fan. The hot exhaust gases flow from the back of the engine, driving it and the aircraft forward.

During operation of gas turbine engines, the temperatures of combustion gases may exceed 3,000° F., considerably higher than the melting temperatures of the metal parts of the engine which are in contact with these gases. Operation of these engines at gas temperatures that are above the metal part melting temperatures is a well-established art, and depends in part on supplying a cooling air to the outer surfaces of the metal parts through various methods. The metal parts of these engines that are particularly subject to high temperatures, and thus require particular attention with respect to cooling, are the metal parts forming combustors and parts located aft of the combustor.

The metal temperatures can be maintained below melting levels by using passageways such as cooling holes incorporated into some engine components. Sometimes, thermal barrier coatings (TBCs) may also be applied to the component by a pressure coating process (e.g., a thermal spray process). However, the thermal spray process and other cleaning processes (e.g., grit blasting, shot peening, water jet washing) often results in overspray that partially or completely blocks the component's cooling holes.

As a result, present coating and cleaning processes involve a multi-step, highly labor intensive process of applying a partial layer of TBC coating, allowing the component and the TBC to sufficiently cool to a temperature at which the component can easily be handled, removing the component from an application fixture on which the thermal spraying takes place, and removing any masking, which is then followed by separately removing the well-cooled, solidified coating from the cooling holes using a water jet or other cleaning methods. To prevent the cooling holes from becoming obstructed beyond a level from which they can be satisfactorily cleaned, only a fraction of the desired TBC thickness is applied prior to cleaning. As a result, the entire process must typically be repeated several times until the desired TBC thickness is reached. This complex process results in low productivity, high cycle time, and increases costs by a factor of five to ten times that of applying the same TBC to a similar non-holed part. Even when coatings are not applied, the pressure cleaning methods used to clean the target surfaces of articles can similarly overflow and obstruct the article's cooling holes.

Accordingly, alternative pressure masking systems would be welcomed in the art.

### BRIEF DESCRIPTION OF THE INVENTION

In one embodiment, a method of treating a target surface of an article comprising one or more passageways is disclosed. The method includes fluidly connecting a pressure masker including pressurized masking fluid to a first side of at least one passageway and passing the pressurized masking fluid through the at least one passageway from the first side to a second side comprising the target surface. The method further includes treating the target surface of the article using a surface treatment system that disposes a surface treating material on the target surface, wherein the pressurized masking fluid passing through the at least one passageway prevents the surface treating material from permanently altering a cross sectional area of the at least one passageway.

In another embodiment, a pressurized masking system for treating a target surface of an article comprising passageways is disclosed. The pressurized masking system includes a pressure masker that fluidly connects to a first side of at least one passageway of the article and passes a pressurized masking fluid through the passageway from the first side to a second side, wherein the second side comprises the target surface. The pressurized masking system further includes a surface treatment system that disposes a surface treating material on the target surface, wherein the pressurized masking fluid prevents the surface treating material from permanently altering a cross sectional area of the at least one passageway.

These and additional features provided by the embodiments discussed herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the inventions defined by the claims. The following detailed description of the illustrative embodiments can be understood when read in conjunction with the following drawings, where like structure is indicated with like reference numerals and in which:

FIG. 1 is a schematic illustrated of a pressure masking system according to one or more embodiments shown or described herein;

FIG. 2 is a perspective view of a pressure masking system according to one or more embodiments shown or described herein;

FIG. 3 is a perspective view of another pressure masking system according to one or more embodiments shown or described herein; and,

FIG. 4 is a method of treating an article using a pressure masking system according to one or more embodiments shown or described herein.

### DETAILED DESCRIPTION OF THE INVENTION

One or more specific embodiments of the present invention will be described below. In an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present invention, the articles “a,” “an,” “the,” and “said” are intended to mean that there are one or more of the elements. The terms “comprising,” “including,” and “having” are intended to be inclusive and mean that there may be additional elements other than the listed elements.

Pressurized masking systems disclosed herein generally comprise a pressure masker and a surface treatment system to coat the target surface of an article comprising passageways. While the surface treatment system disposes surface treating material on the target surface, pressurized masking fluid is fluidly connected to the passageways and passed there through to prevent the permanent altering a cross sectional area of the passageway of the passageways by the surface treating material. Pressurized masking systems, and methods of pressure treating a target surface of an article will be discussed in more detail herein.

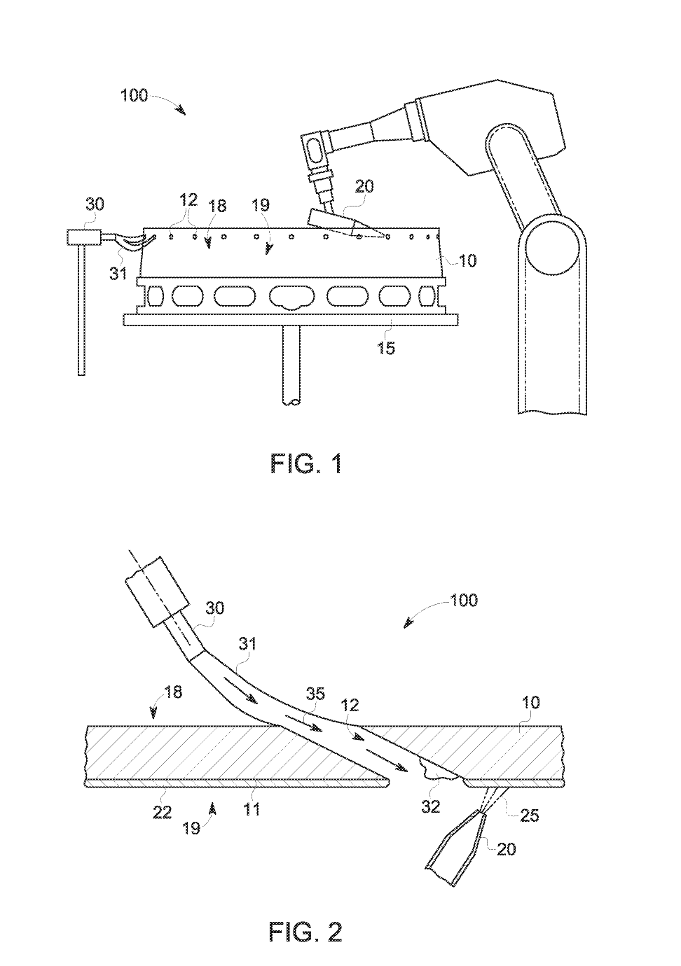

Referring now to FIGS. 1-3, a pressurized masking system 100 is illustrated comprising a surface treatment system 20 and a pressure masker 30 for treating an article 10. The article 10 comprises one or more passageways 12 passing through the article 10 from a first side 18 to a second side 19. As discussed above, the article 10 can comprise a variety of different components of a turbine. For example, the article 10 can comprise a liner, bucket, blade, vane, nozzle, or shroud. In some embodiments, the article 10 can comprise a turbine component such as a hot gas path component or a combustion component. In other embodiments, the article 10 can comprise any other component of a turbine such as a component for a gas turbine, industrial gas turbine, steam turbine or the like. The passageways 12 can comprise any passage through the article 10 (passing from the first side 18 to the second side 19) that is intended to remain open (such that air can pass through) when the article 10 is in use. For example, in some embodiments the passageways 12 may comprise cooling holes.

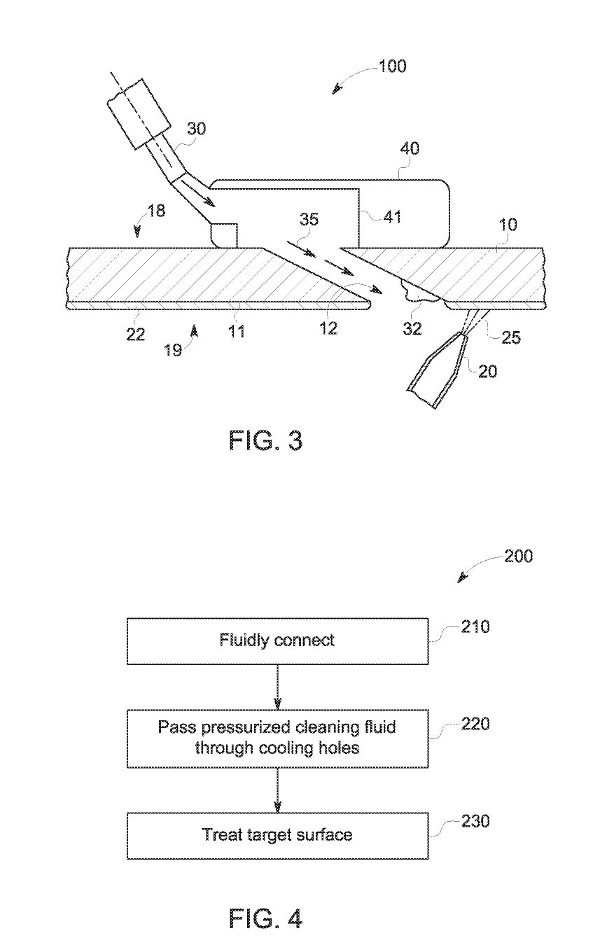

As best illustrated in FIGS. 2-3, the second side 19 of the article 10 comprises a target surface 11 that is to be coated. The target surface 11 may be coated prior to first use, during routine or repair maintenance, or as otherwise necessary depending on the life of the article 10. As used herein, “coated” refers to at least partially applying a new material to a surface such as through the use of a thermal spray gun or the like as will become appreciated herein.

In some embodiments, such as when the article 10 comprises a hot gas path component, the target surface 11 of the article 10 may have a thermal barrier coating (“TBC”) coated thereon prior to operation. The TBC can comprise one or more layers of metal and/or ceramic surface treating material applied to the target surface 11 of the article 10 to impede the transfer of heat from hot combustion gases to the article 10, thus insulating the component from the hot combustion gas. The presence of the TBC on the surface permits the combustion gas to be hotter than would otherwise be possible with the particular material and fabrication process of the component. Any suitable composition of TBC may be applied. For example, in some embodiments the TBC can comprise a bond layer of MCrAlY, wherein M is preferably Ni, Co, or a combination thereof, followed by a layer of yttria stabilized zirconia (YSZ).

In some embodiments, the article 10 may be disposed on a support stand 15 prior to or during the pressure treating as will become appreciated herein. The support stand 15 may be stationary or mobile (e.g., rotatable) and position the article 10 relative to the surface treatment system 20 and the pressure masker 30 when treating the target surface 11 of the article 10.

Still referring to FIGS. 1-3, the pressurized masking system 100 further comprises the surface treatment system 20. The surface treatment system 20 comprises any device that disposes a surface treating material 25 on the target surface 11 of the article 10 to form a permanent or temporary coating 22 or the like. For example, in some embodiments, the surface treatment system 20 can comprise a thermal spray gun. In such embodiments, the pressurized surface treating material 25 can comprise pressurized gas or a pressurized liquid (e.g., as water). In other embodiments, the surface treatment system 20 can comprise any other device that disposes surface treating material 25 on the target surface 11 of the article 10.

The surface treatment system 20 may be disposed at any position relative to the article 10 that allows for the treating of the target surface 11. As used herein, “treating” refers to any operation that mechanically, chemically or otherwise modifies at least a portion of the surface of the article. For example, treating can include, but is not limited to, coating, stripping, cleaning, cladding or the like and may be achieved through a variety of surface treatment systems 20 as will become appreciated herein.

For example, as illustrated in FIG. 1, in some embodiments the article 10 may be disposed on a support stand 15 adjacent the surface treatment system 20. The support stand 15 may then be able to rotate or otherwise displace the article 10 with respect to the surface treatment system 20 and/or the surface treatment system 20 may be able to articulate with respect to the article 10. The surface treatment system 20 may then be used to dispose the surface treating material 25 on the target surface 11 of the article 10. However, as a result of surface treating material 25 being disposed on the target surface 11 of the article 10, some of the surface treating material 25 may enter one or more of the passageways 12 from the second side 19 of the article 10. As such, some of the surface treating material 25 may potentially form obstructions 32 in the one or more passageways 12 if left unopposed.

The surface treatment system 20 may be used for a variety of applications to coat, strip or otherwise treat the target surface 11 of the article 10. For example in some embodiments the surface treatment system 20 may be used to coat the target surface with a TBC as discussed above. In some embodiments, the surface treatment system 20 may be used to apply a bond coat to the target surface 11 for the subsequent application of a TBC or other coating. In some embodiments, the surface treatment system 20 may be used to apply a paint coat to the target surface 11. In some embodiments, the surface treatment system 20 may be used to apply other coatings such as diffusion coatings, DVC TBC, HVOF or other adhesive bonding coatings.

In some embodiments, the surface treatment system 20 can comprise a cladding system. The cladding system can comprise any system capable of bonding together dissimilar metals, one of which comprises the target surface 11 of the article 10. For example, in some embodiments the cladding system can comprise a laser cladding system. In such embodiments, the surface treating material 25 can comprise a powder material or other feedstock material that is disposed onto the target surface 11 of the article 10 and subsequently melted via one or more lasers. In such embodiments, the pressurized masking fluid can pass through the at least one passageway 12 (e.g., cooling holes) of the article 10 to prevent the powder material from permanently altering a cross sectional area of the passageway 12 as will become appreciated herein. In other embodiments, the cladding system can comprise any other variety of cladding system, material and/or operating parameters.

In other embodiments, the surface treatment system 20 can comprise a plating system. The plating system can comprise any system capable of depositing a metal or alloy on at least a portion of the target surface 11 of the article 10 when the target surface. For example, in some embodiments, the plating system can comprise an electroplating system such as those that involve transferring metal ions in a solution to a plating of the target surface 11 by forming an anode and cathode relationship and running a current there between. The electroplating system can dispose the surface treating material 25 through the use of solutions and/or brushings as appreciated to those skilled in the art. Such plating systems can be used to plate a variety of surface treating materials including various metals (e.g., zinc, chrome, tin, rhodium, gold, silver) or alloys.

In even some embodiments, the surface treatment system 20 can comprise a diffusion coating system. The diffusion coating system can comprise any system capable of coating at least a portion of the target surface 11 of the article by heating a diffusing one or more surface treating materials 25 disposed thereon. For example, for diffusion coating systems, the surface treating materials 25 can include aluminum, chromium, silicon or the like and may be disposed on at least a portion of the target surface 11 of the article 10 by various slurry, powder-paint, or pack cementation methods or the like. In some embodiments, the diffusion coating system can comprise heating the surface treating material 25 while undergoing gas-phase deposition, chemical vapor deposition or the like.

In yet other embodiments, the surface treatment system 20 can comprise a stripping system. The stripping system can comprise any system that deposits the surface treating material 25 on the target surface 11 of the article 10 to at least partially remove at least a portion of the target surface 11. For example, in some embodiments, the stripping system can comprise hydrolysis system that chemically cleaves bonds on the target surface 11 by disposing at least water thereon. Various other chemicals or compounds may also be incorporated depending on the chemistry of the target surface 11 that is to be stripped. In other embodiments, the stripping system can comprise any other system that can at least partially remove at least a portion of the target surface 11 such as chemical etching or the like.

While specific embodiments have been presented herein, it should be appreciated that these are exemplary only and any other application of the surface treatment system 20 as part of the pressurized masking system 100 may also be realized.

Referring still to FIGS. 1-3, the pressurized masking system 100 further comprises a pressure masker 30. The pressure masker 30 comprises a fluid connection 31 that fluidly connects a source of masking fluid 35 to at least one passageway 12 of the article 10. As used herein, “fluid connection” refers to a connection that allows the pressurized masking fluid 35 to pass from the pressure masker 30 to the passageway 12 with negligent loss to the outside environment. The fluid connection can comprise, for example, flexible tubes, hoses, pipes or any other conduit that directs the passage of the pressurized masking fluid 35 to the one or more passageways 12.

In one embodiment, such as that illustrated in FIG. 2, the fluid connection 31 may comprise a tube that directly connects the output of the pressure masker 30 to the first side 18 of the passageway 12. In some embodiments, the fluid connection 31 may comprise a single tube between the pressure masker 30 and a single passageway 12 (such as that illustrated in FIG. 2). In other embodiments, the fluid connection may comprise a single tube leaving the pressure masker 30 that breaks off into segments that connect to a plurality of passageways 12 (such as that illustrated in FIG. 1). In even other embodiments, the fluid connection 31 may comprise a plurality of tubes leaving the pressure masker 30 that connects to a single or a plurality of passageways 12. For example, the fluid connection 31 may comprise a plurality of channels of similar or dissimilar pressurized masking fluids 35 that connect to two or more passageways. Moreover, the plurality of channels may comprise different pressures, temperatures, directions or mixtures of pressurized masking fluids 35. It should be appreciated that any other configuration that provides a fluid connection 31 between the pressure masker 30 and one or more passageways 12 may alternatively or additionally be realized.

For example, referring now to FIG. 3, in some embodiments the fluid connection 31 may comprise a multi-outlet manifold connection 40 comprising an internal passage 41 that can receive pressurized masking fluid 35 from the pressure masker 30 and fluidly distribute it to one or more passageways. The multi-outlet manifold connection 40 can thereby attach directly to the first side 18 of the article 10 and distribute the pressurized masking fluid 35 to a wide area about the article 10. Any passageways 12 within that area will thereby have pressurized masking fluid 35 fluidly pass there through.

The pressurized masking fluid 35 can comprise any medium that can pass through the passageway 12 with a positive energy and prevent the permanent altering of a cross sectional area of the at least one passageway by the surface treating material 25 (or particulates thereof). As used herein, “prevent the permanent altering of a cross sectional area” (and variants thereof) refers to removing and/or preventing substantially all of the surface treating material 25 that may enter the passageway 12 so that the cross sectional area of the passageway is not substantially reduced by a permanent obstruction 32 or increased due to erosion, deformation or the like. It should be appreciated that a thin coating of the interior walls directly proximate the second side 19 of the surface treating material 25 is not considered to permanently alter the cross sectional area of the passageway 12 as any such reduction would be relatively minimal and not noticeably affect the flow of air through the passageway 12 during operation. Examples of obstructions that would permanently alter the cross sectional area of the passageway 12 include, for example, large particulates lodged against a wall, a clumping of surface treating material 25 or the like. The pressurized masking fluid 35 may thereby comprise any material that can be forced through the one or more passageways 12 at a masking pressure to impact on and remove potential obstructions 32 from the surface treating material 25 that would alter the cross sectional area.

For example, in some embodiments, the pressurized masking fluid 35 may comprise a gas such as inert gas or nitrogen. In some embodiments, the pressurized masking fluid 35 may comprise water with or without abrasives distributed therein. While specific embodiments of pressurized masking fluid 35 and surface treatment systems have been presented herein, it should be appreciated that additional and alternative pressurized masking fluids and surface treatment systems may also be realized. Moreover, the pressurized masking fluid 35 may comprise a masking pressure that is greater than, equal to, or less than a treating pressure of the surface treating material 25 so long as the pressurized masking fluid 35 has enough energy to remove obstructions 32 from the passageways 12. In some embodiments, the masking pressure may comprise a positive pressure such that the positive pressure pushes the pressurized masking fluid 35 through the passageway 12. In other embodiments, the masking pressure may comprise a negative pressure (such as via a vacuum or suction element on the second side 19 of the article 10 such that the negative pressure pulls the pressurized masking fluid 35 through the passageway 12. In some embodiments, the masking pressure may comprise a variable pressure that fluctuates during the masking process.

In operation, the pressure masker 30 thereby passes the pressurized masking fluid 35 through the at least one passageway 12 at a masking pressure from the first side 18 to the second side 19 (wherein the second side 19 comprises the target surface 11 of the article 10 that is to be coated). Likewise, the surface treatment system 20 treats the target surface 11 of the article 10 by disposing surface treating material 25 on the target surface. As discussed above, this can include a variety of systems such as cladding systems, plating systems, diffusion systems, or stripping systems. As a result of flow pattern distributions, some of the surface treating material 25 may enter one or more passageways 12 and form one or more obstructions 32. For example, the obstructions 32 may comprise a grouping of particulates from the surface treating material that would decrease the cross sectional area of the passageway 12 and reduce the amount of air that could flow there through. However, to prevent the surface treating material 25 from permanently obstructing the at least one passageway 12 (and altering its cross sectional area), the pressurized masking fluid 35 will contact the obstruction 32 and push it back out of the passageway 12. In some embodiments, the pressurized masking fluid 35 may prevent any obstructions 32 from even entering the passageways 12 via the pressurized masking fluid 35 exiting the passageway 12 on the second side 19 of the article 10.

Referring now to FIGS. 1-4, a method 200 is illustrated for treating a target surface 11 of an article 10 comprising one or more passageways 12. The method 200 first comprises fluidly connecting the pressure masker 30 to a first side 18 of at least one passageway 12 of the article 10 in step 210. As discussed above, the fluid connection 31 may comprise a variety of configurations and may connect any type of pressure masker 30 to any number of passageways 12. The pressure masker 30 then passes pressurized masking fluid 35 through the at least one passageway from the first side 18 to the second side 19 in step 220. Likewise, the surface treatment system 20 treats the target surface 11 on the second side 19 of the article 10 by disposing surface treating material 25 on the target surface 11 in step 230.

It should be appreciated that passing pressurized masking fluid 35 through the at least one passageway 12 in step 220 and treating the target surface 11 in step 230 may start and end simultaneously or with relative delay. For example, in some embodiments the pressurized masking fluid 35 may already be passing through the passageway 12 in step 20 prior to the initiation of treating the target surface 11 in step 230. Such embodiments may prevent a buildup of obstructions 32 prior to activation of the pressure masker 30. In some embodiments, the pressurized masking fluid 35 may continue to pass through the passageway 12 in step 220 after the article 10 is treated in step 230. Such embodiments may help ensure any obstacles 32 remaining in the passageways 12 after treating is complete in step 230 are still removed by the pressurized masking fluid 35.

It should now be appreciated that pressurized masking systems may be used to treat the target surface of an article while preventing the permanent altering of a cross sectional area of one or more passageways. The use of a fluid connection between the pressure masker and the one or more passageways can prevent the need for physical masking barriers such as tape, wax or the like potentially providing a more efficient treating system.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

What is claimed is:

1. A method of treating a target surface of an article comprising one or more passageways, the method comprising:
fluidly connecting a pressure masker comprising pressurized masking fluid to a first side of at least one passageway;
passing the pressurized masking fluid through the at least one passageway from the first side to a second side comprising the target surface; and,
treating the target surface of the article using a surface treatment system that disposes a surface treating material on the target surface, wherein the pressurized masking fluid passing through the at least one passageway prevents the surface treating material from permanently altering a cross sectional area of the at least one passageway.

2. The method of claim 1, wherein the surface treatment system comprises a cladding system.

3. The method of claim 2, wherein the surface treating material comprises a powder material such that the pressurized masking fluid passing through the at least one passageway prevents the powder material from permanently altering a cross sectional area of the at least one passageway.

4. The method of claim 1, wherein the surface treatment system comprises a plating system.

5. The method of claim 4, wherein the surface treatment system comprises an electroplating system.

6. The method of claim 1, wherein the surface treatment system comprises a diffusion coating system.

7. The method of claim 1, wherein the surface treatment system comprises a surface stripping system that deposits the surface treating material on the target surface to at least partially remove at least a portion of the target surface.

8. The method of claim 7, wherein the surface stripping system comprises a hydrolysis system.

9. The method of claim 1, wherein the article comprises a turbine component.

10. The method of claim 9, wherein the one or more passageways comprise cooling holes in the turbine component.

11. A pressurized masking system for treating a target surface of an article comprising passageways, the pressurized masking system comprising:
a pressure masker that fluidly connects to a first side of at least one passageway of the article and passes a pressurized masking fluid through the passageway from the first side to a second side, wherein the second side comprises the target surface; and,
a surface treatment system that disposes a surface treating material on the target surface, wherein the pressurized masking fluid prevents the surface treating material from permanently altering a cross sectional area of the at least one passageway.

12. The pressurized masking system of claim 11, wherein the surface treatment system comprises a cladding system.

13. The pressurized masking system of claim 12, wherein the surface treating material comprises a powder material such that the pressurized masking fluid passing through the at least one passageway prevents the powder material from permanently altering a cross sectional area of the at least one passageway.

14. The pressurized masking system of claim 11, wherein the surface treatment system comprises a plating system.

15. The pressurized masking system of claim 14, wherein the surface treatment system comprises an electroplating system.

16. The pressurized masking system of claim 11, wherein the surface treatment system comprises a diffusion coating system.

17. The pressurized masking system of claim 11, wherein the surface treatment system comprises a surface stripping system that deposits the surface treating material on the target surface to at least partially remove at least a portion of the target surface.

18. The pressurized masking system of claim 17, wherein the surface stripping system comprises a hydrolysis system.

19. The pressurized masking system of claim 11, wherein the article comprises a turbine component.

20. The pressurized masking system of claim 19, wherein the passageways comprise cooling holes in the turbine component
